(19) United States
(12) Patent Application Publication
(10) Pub. No.: US 2025/0013213 A1
(43) Pub. Date: Jan. 9, 2025

(54) ANALYSIS APPARATUS, SUBSTRATE PROCESSING SYSTEM, SUBSTRATE PROCESSING APPARATUS, ANALYSIS METHOD, AND ANALYSIS PROGRAM

(71) Applicant: Tokyo Electron Limited, Tokyo (JP)

(72) Inventors: Ken HIRANO, Miyagi (JP); Takari YAMAMOTO, Miyagi (JP); Takashi KUBO, Miyagi (JP); Haruki OMINE, Sapporo City (JP); Masaki KITSUNEZUKA, Sapporo City (JP); Toshihiro KITAO, Sapporo City (JP)

(73) Assignee: Tokyo Electron Limited, Tokyo (JP)

(21) Appl. No.: 18/884,523

(22) Filed: Sep. 13, 2024

Related U.S. Application Data
(63) Continuation of application No. PCT/JP2023/009835, filed on Mar. 14, 2023.

(30) Foreign Application Priority Data
Mar. 24, 2022 (JP) 2022-048877

(51) Int. Cl. G05B 13/04; G05B 13/02

(52) U.S. Cl. CPC G05B 13/042; G05B 13/0265

(57) ABSTRACT

An analysis apparatus, a substrate processing system, a substrate processing apparatus, an analysis method, and an analysis program improve adjustment accuracy in adjusting the temperature of a substrate. The analysis apparatus includes circuitry that performs training to generate a trained model using setting parameters for temperature adjustment elements in regions divided from a substrate support in a process space in a first vacuum environment and using a first temperature data set that is data of temperatures at positions on a substrate supported by the substrate support, and that calculates setting parameters for the temperature adjustment elements corresponding to a target temperature of the substrate using the trained model.

### CROSS-REFERENCE TO RELATED APPLICATIONS

This application is the Continuation of PCT/JP2023/009835 filed on Mar. 14, 2023, which claims priority under 35 U.S.C. § 119 (a) to Japanese Patent Application No. JP2022-048877 filed on Mar. 24, 2022, all of which are hereby expressly incorporated by reference into the present application.

### FIELD

The disclosure relates to an analysis apparatus, a substrate processing system, a substrate processing apparatus, an analysis method, and an analysis program.

### BACKGROUND

A known substrate processing apparatus includes temperature adjustment elements (e.g., heaters) in different regions of an electrostatic chuck or ESC (a substrate support that supports a substrate) in a chamber in a vacuum environment, and adjusts the temperature of a substrate for each region (refer to, for example, Patent Literature 1). The substrate processing apparatus is to appropriately adjust the temperature of a substrate toward a target temperature.

When the setting temperatures for the temperature adjustment elements in the regions are set to the target temperature, the entire substrate may not uniformly have the target temperature. For example, locally uneven temperatures caused by, for example, machine differences may cause the in-plane average temperature of the substrate to be different from the target temperature, thus possibly lowering adjustment accuracy.

### CITATION LIST

### Patent Literature

Patent Literature 1: Japanese Unexamined Patent Application Publication No. 2020-009795

### BRIEF SUMMARY

### Technical Problem

One or more aspects of the disclosure are directed to an analysis apparatus, a substrate processing system, a substrate processing apparatus, an analysis method, and an analysis program that improve adjustment accuracy in adjusting the temperature of a substrate.

### Solution to Problem

An analysis apparatus according to one aspect of the disclosure provides, for example, the structure described below. The analysis apparatus includes a trainer that performs training to generate a trained model using setting parameters for temperature adjustment elements in regions divided from a substrate support in a process space in a first vacuum environment and using a first temperature data set that is data of temperatures at positions on a substrate supported by the substrate support, and a calculator that calculates setting parameters for the temperature adjustment elements corresponding to a target temperature of the substrate using the trained model.

### Advantageous Effects

The analysis apparatus, the substrate processing system, the substrate processing apparatus, the analysis method, and the analysis program according to the above aspect of the disclosure improve the adjustment accuracy in adjusting the temperature of a substrate.

### BRIEF DESCRIPTION OF DRAWINGS

FIG. 1 is a diagram describing overall processing performed by a substrate processing system in different phases.

FIG. 2 is a diagram of a substrate processing apparatus showing its example structure.

FIG. 3 is a top view of an example electrostatic chuck (ESC) included in the substrate processing apparatus.

FIG. 4 is a circuit diagram of an example power supply unit included in the substrate processing apparatus.

FIG. 5 is a block diagram of an analysis apparatus showing its example hardware configuration.

FIG. 6 is a diagram of the substrate processing system showing its example functional components (in a pre-training phase).

FIG. 7 is a diagram showing specific examples of pre-training data and processing performed by a pre-trainer.

FIG. 8 is a diagram of the substrate processing system showing its example functional components (in an additional training phase).

FIG. 9 is a diagram showing specific examples of additional training data and processing performed by an additional trainer and a setting temperature calculator.

FIG. 10 is a first flowchart of an example analysis process.

FIG. 11 is a graph showing example changes in the adjustment accuracy.

FIG. 12 is a second flowchart of an example analysis process.

### DETAILED DESCRIPTION

Embodiments will now be described with reference to the accompanying drawings. Like reference numerals denote components having substantially the same functions herein and in the drawings. Such components will not be described repeatedly.

### First Embodiment

### Overview of Substrate Processing System

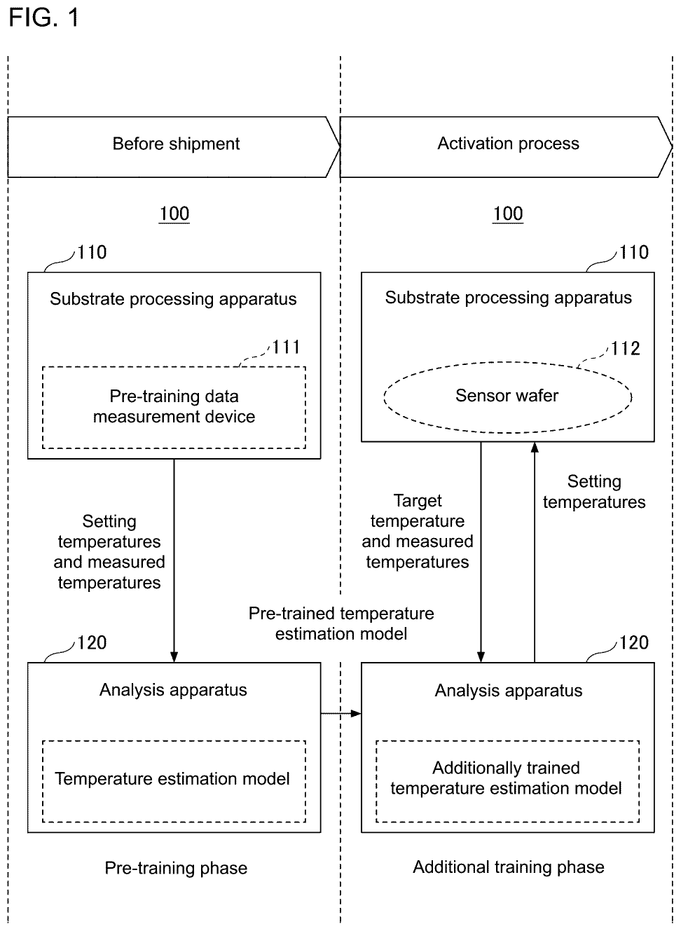

Overall processing performed by a substrate processing system according to a first embodiment will be described first for each of multiple phases. FIG. 1 is a diagram describing overall processing performed by the substrate processing system in each phase.

As shown in FIG. 1, a substrate processing system 100 includes a substrate processing apparatus 110 and an analysis apparatus 120. The substrate processing system 100 performs processing for improving adjustment accuracy in adjusting the temperature of a substrate through a pre-training phase and an additional training phase.

In the pre-training phase before shipment, the substrate processing system 100 includes a pre-training data measurement device 111 installed in the substrate processing apparatus 110. The pre-training data measurement device 111 measures the surface temperature of a substrate when heaters in regions of an electrostatic chuck or ESC (substrate support) described later operate at various setting temperatures, and obtains the measured temperatures.

In the substrate processing system 100 in the pre-training phase before shipment, the setting temperatures set for the multiple heaters and the measured temperatures obtained by operating the heaters at the setting temperatures are stored into the analysis apparatus 120 as pre-training data.

In the substrate processing system 100 in the pre-training phase before shipment, the analysis apparatus 120 performs pre-training on a temperature estimation model using the pre-training data, and generates a pre-trained temperature estimation model (an example trained model).

In the additional training phase in an activation process at a destination, the substrate processing system 100 includes a sensor wafer 112 loaded in the substrate processing apparatus 10.

In the present embodiment, the substrate processing apparatus 110 used in the additional training phase and the substrate processing apparatus 110 used in the pre-training phase are separate substrate processing apparatuses of the same type.

In the present embodiment, the ESC included in the substrate processing apparatus 110 in the additional training phase and the ESC included in the substrate processing apparatus 110 in the pre-training phase are separate ESCs of the same type.

In other words, the ESC included in the substrate processing apparatus 110 in the additional training phase and the ESC included in the substrate processing apparatus 110 in the pre-training phase have machine differences between them in the present embodiment. The ESC included in the substrate processing apparatus 110 in the additional training phase may be the same ESC included in the substrate processing apparatus 110 in the pre-training phase.

In the additional training phase in the activation process at the destination, the substrate processing system 100 operates the heaters in the regions of the ESC at the respective setting temperatures corresponding to a target temperature. The substrate processing system 100 in the additional training phase then measures the temperature of a substrate at that time with the sensor wafer 112 that has been loaded. Operating the heaters at the respective setting temperatures refers to controlling the heaters to have electrical resistances corresponding to the respective setting temperatures.

In the additional training phase in the activation process at the destination, the substrate processing apparatus 110 in the substrate processing system 100 transmits the target temperature and the measured temperatures to the analysis apparatus 120.

In the present embodiment, the analysis apparatus 120 is located adjacent to the substrate processing apparatus 110 at the destination and connected to the substrate processing apparatus 110 for mutual communication. The analysis apparatus 120 may be located differently. The analysis apparatus 120 may be located away from the substrate processing apparatus 110 at the destination (or may be located, for example, in the cloud).

In the additional training phase in the activation process at the destination, the analysis apparatus 120 in the substrate processing system 100 calculates the setting temperatures corresponding to the target temperature using the pre-trained temperature estimation model (using pre-trained model parameters). The substrate processing apparatus 110 can thus operate the heaters at the setting temperatures calculated by the analysis apparatus 120 and corresponding to the target temperature.

In the additional training phase the activation process at the destination, the analysis apparatus 120 in the substrate processing system 100 associates the target temperature and the measured temperatures transmitted from the substrate processing apparatus 110 with the setting temperatures, and stores them as additional training data. The analysis apparatus 120 performs additional training on the pre-trained temperature estimation model to generate an additionally trained temperature estimation model. Additionally, the analysis apparatus 120 newly calculates the setting temperatures corresponding to the target temperature using the generated additionally trained temperature estimation model (using additionally trained model parameters). The substrate processing apparatus 110 can thus operate the heaters at the setting temperatures newly calculated by the analysis apparatus 120 and corresponding to the target temperature.

The setting temperatures corresponding to the target temperature refer to setting temperatures (setting temperatures set for the respective heaters in the regions) that reduce variation in the measured temperatures at positions on the substrate and also yields an average (in-plane average temperature) of the measured temperatures at the positions on the substrate closer to the target temperature.

As described above, in the additional training phase in the activation process at the destination, the substrate processing system 100 calculates the setting temperatures using the pre-trained temperature estimation model (using the pre-trained model parameters), and repeats the operation of the heaters at the calculated setting temperatures, the measurement of the temperatures of the substrate, the additional training using the setting temperatures and the measured temperatures, and the calculation of the setting temperatures using the additionally trained temperature estimation model until a predetermined condition is determined to be satisfied. The analysis apparatus 120 can thus derive the setting temperatures that achieve higher adjustment accuracy as the setting temperatures corresponding to the target temperature. The predetermined condition refers to a condition that the variation in the measured

temperatures at the positions on the substrate is less than or equal to a predetermined threshold and the difference between the average (in-plane average temperature) of the measured temperatures at the positions on the substrate and the target temperature is less than or equal to a predetermined threshold.

The setting temperatures that achieve higher adjustment accuracy refer to setting temperatures that reduce the variation in the measured temperatures at the positions on the substrate and also yields an average (in-plane average temperature) of the measured temperatures at the positions on the substrate closer to the target temperature.

In other words, the substrate processing apparatus 110 can operate the heaters at the setting temperatures (with electrical resistances corresponding to the setting temperatures) that achieve higher adjustment accuracy as the setting temperatures corresponding to the target temperature.

The substrate processing apparatus 110 in the additional training phase can thus improve the adjustment accuracy in adjusting the temperature of a substrate.

### Structure of Substrate Processing Apparatus

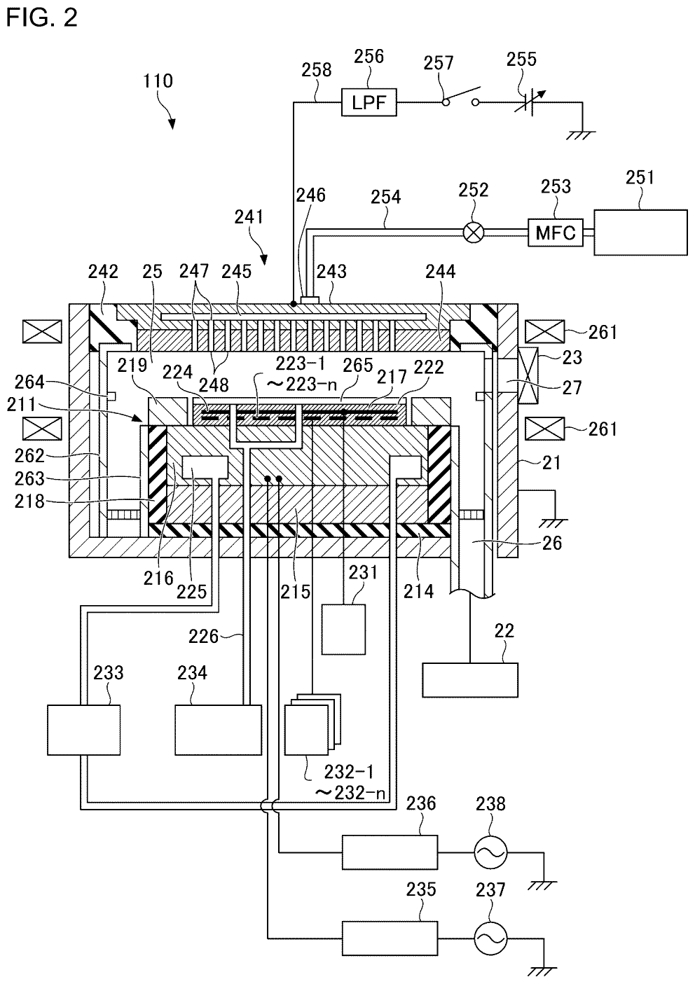

The detailed structure of the substrate processing apparatus 110 will now be described with reference to FIGS. 2 to 4.

### 1. Overall Structure

FIG. 2 is a diagram of a substrate processing apparatus showing its example structure. As shown in FIG. 2, the substrate processing apparatus 110 includes a chamber 21, an exhaust device 22, and a gate valve 23.

The chamber 21 is formed from aluminum and is substantially cylindrical. The chamber 21 has a surface covered with an anodic oxide film. The chamber 21 has a processing space 25 inside. The chamber 21 isolates the processing space 25 from the outside atmosphere. The chamber 21 has an outlet 26 and an opening 27.

The chamber 21 has the outlet 26 in its bottom. The chamber 21 has the opening 27 in its sidewall. The exhaust device 22 is connected with the processing space 25 in the chamber 21 through the outlet 26. The exhaust device 22 discharges gases from the processing space 25 through the outlet 26 and decompresses the processing space 25 to a predetermined degree of vacuum. The gate valve 23 opens or closes the opening 27.

### (2) Structure of Mount 211

As shown in FIG. 2, the substrate processing apparatus 110 further includes a mount 211. The mount 211 is located in a lower portion of the processing space 25. The mount 211 includes an insulating plate 214, a support 215, a base 216, an ESC (electrostatic chuck) 217 (substrate support), an inner wall 218, an edge ring 219, an electrostatic clamp electrode 224, and multiple heaters 223-1 to 223-n (n=2, 3, 4, . . . ).

The insulating plate 214 is formed from an insulator and supported on the bottom of the chamber 21. The support 215 is formed from a conductor. The support 215 is located on the insulating plate 214. The support 215 is supported on the bottom of the chamber 21 with the insulating plate 214 between them to be electrically insulated from the chamber 21.

The base 216 is formed from a conductor such as aluminum. The base 216 is located on the support 215. The base 216 is supported on the bottom of the chamber 21 with the support 215 between them. The ESC 217 is located on the base 216. The ESC 217 is supported on the bottom of the chamber 21 with the base 216 between them. The ESC 217 is formed from an insulator. The electrostatic clamp electrode 224 and the multiple heaters 223-1 to 223-n are embedded in the ESC 217.

The inner wall 218 is formed from an insulator such as quartz. The inner wall 218 is cylindrical. The inner wall 218 is located around the base 216 and the support 215 to allow the base 216 and the support 215 to be located inward from the inner wall 218. The inner wall 218 surrounds the base 216 and the support 215.

The edge ring 219 is formed from, for example, monocrystalline silicon. The edge ring 219 is annular. The edge ring 219 is placed along the outer circumference of the ESC 217 to allow the ESC 217 to be located inward from the edge ring 219. The edge ring 219 surrounds the ESC 217. The mount 211 further has a refrigerant circulation channel 225 and a heat transfer gas supply channel 226. The refrigerant circulation channel 225 is defined inside the base 216. The heat transfer gas supply channel 226 extends through the ESC 217. The heat transfer gas supply channel 226 has ends defined in an upper surface 222 of the ESC 217.

The substrate processing apparatus 110 further includes a direct current (DC) power supply 231, multiple power supply units 232-1 to 232-n, a chiller unit 233, and a heat transfer gas supply unit 234. The DC power supply 231 is electrically coupled to the electrostatic clamp electrode 224 in the ESC 217. The DC power supply 231 applies a DC voltage to the electrostatic clamp electrode 224 to cause a substrate 265 to be held on the ESC 217 with a Coulomb force. The multiple power supply units 232-1 to 232-n correspond to the respective heaters 223-1 to 223-n. The chiller unit 233 is connected with the refrigerant circulation channel 225. The chiller unit 233 cools a refrigerant to a predetermined temperature and circulates the cooled refrigerant through the refrigerant circulation channel 225 in the base 216. The heat transfer gas supply unit 234 is connected with the heat transfer gas supply channel 226. The heat transfer gas supply unit 234 supplies a heat transfer gas such as a He gas to the heat transfer gas supply channel 226.

The substrate processing apparatus 110 further includes a first radio-frequency (RF) power supply 237 and a second RF power supply 238. The first RF power supply 237 is connected to the base 216 with a first matcher 235 between them. The second RF power supply 238 is connected to the base 216 with a second matcher 236 between them. The first RF power supply 237 for plasma generation provides RF power with a predetermined frequency (e.g., 100 MHz) to the base 216. The second RF power supply 238 for biasing provides, to the base 216, RF power with a frequency (e.g., 13 MHz) lower than the frequency of the RF power provided to the base 216 from the first RF power supply 237.

### (3) Structure of Shower Head 241

As shown in FIG. 2, the substrate processing apparatus 110 further includes a shower head 241. The shower head 241 is located above the mount 211 in the processing space 25 with the lower surface of the shower head 241 facing the mount 211 and a plane parallel to the lower surface of the shower head 241 that is substantially parallel to a plane parallel to the upper surface of the mount 211. The shower head 241 includes an insulating member 242, a body 243, and an upper ceiling plate 244.

The insulating member 242 is formed from an insulator and supported by an upper portion of the chamber 21. The body 243 is formed from, for example, a conductor such as aluminum with a surface processed with anodic oxidation. The body 243 is supported by the chamber 21 with the insulating member 242 between them to be electrically insulated from the chamber 21. The body 243 and the base 216 are respectively used as a primary upper electrode and a primary lower electrode. The upper ceiling plate 244 is formed from a silicon-containing substance such as quartz. The upper ceiling plate 244 is located below a lower portion of the body 243 and supported by the body 243 to be attachable to and detachable from the body 243.

The body 243 has a gas-diffusion compartment 245, a gas inlet 246, and multiple gas outlets 247. The gas-diffusion compartment 245 is defined inside the body 243. The gas inlet 246 is defined above the gas-diffusion compartment 245 in the body 243 and connects with the gas-diffusion compartment 245. The upper ceiling plate 244 has multiple gas inlets 248. The multiple gas inlets 248 extend through the upper ceiling plate 244 from the upper surface of the upper ceiling plate 244 to the lower surface of the upper ceiling plate 244 and connect with the respective multiple gas outlets 247.

The substrate processing apparatus 110 further includes a process gas supply source 251, a valve 252, and a mass flow controller 253. The process gas supply source 251 is connected to the gas inlet 246 in the body 243 of the shower head 241 through a pipe 254. The mass flow controller 253 is located in the pipe 254. The valve 252 is located between the mass flow controller 253 and the gas inlet 246 in the pipe 254. The valve 252 is opened or closed to supply a process gas from the process gas supply source 251 to the gas inlet 246 or to stop a process gas from being supplied from the process gas supply source 251 to the gas inlet 246.

The substrate processing apparatus 110 further includes a variable DC power supply 255, a low-pass filter 256, and a switch 257. The variable DC power supply 255 is electrically coupled to the body 243 of the shower head 241 with an electric circuit 258. The low-pass filter 256 and the switch 257 are located in the electric circuit 258. The switch 257 is opened or closed to apply a DC voltage to the shower head 241 or to stop a DC voltage from being applied to the shower head 241.

### (4) Structure of Ring Magnet 261

The substrate processing apparatus 110 further includes a ring magnet 261. The ring magnet 261 is an annular permanent magnet. The ring magnet 261 is concentric with the chamber 21, which is located inward from the ring magnet 261. The ring magnet 261 is rotatably supported by the chamber 21 with a rotator (not shown) between them. The ring magnet 261 generates a magnetic field in a space between the shower head 241 and the mount 211 in the processing space 25.

### (5) Structure of Inner Wall Surface of Chamber 21

The substrate processing apparatus 110 further includes a deposition shield 262, a

deposition shield 263, and a conductive member 264. The deposition shield 262 covers the inner wall surface of the chamber 21 and is supported by the chamber 21 to be attachable to and detachable from the chamber 21. The deposition shield 262 prevents etching byproducts (deposition) from adhering to the inner wall surface of the chamber 21. The conductive member 264 is located, in the processing space 25, at substantially the same level as the substrate 265 mounted on the mount 211. The conductive member 264 is supported on the deposition shield 262. The conductive member 264 is formed from a conductor and electrically connected to the ground. The conductive member 264 reduces abnormal discharge in the chamber 21.

### (6) Structure of ESC 217

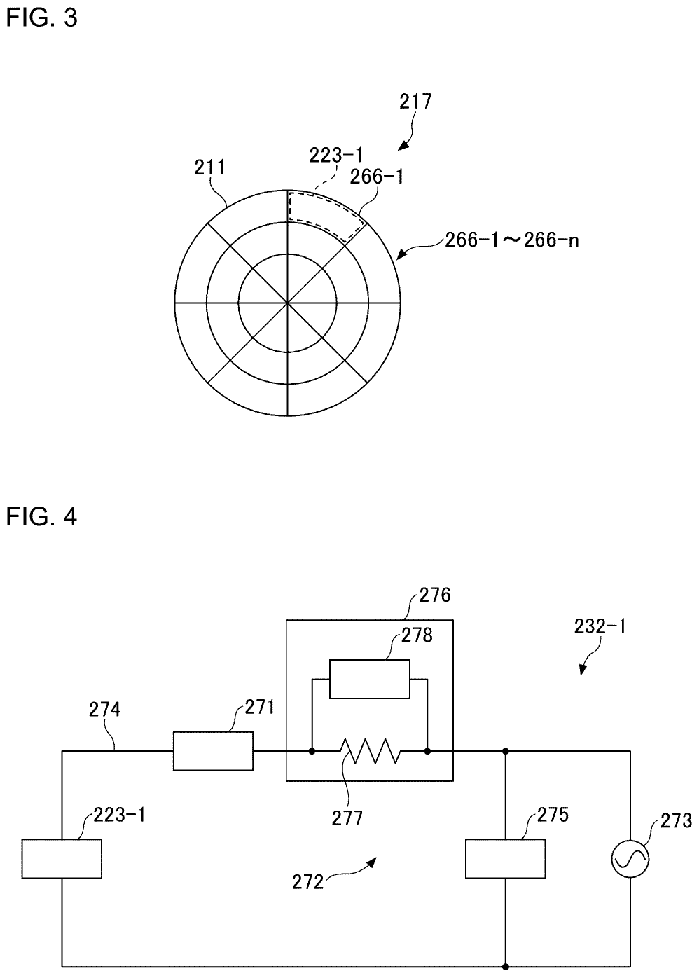

FIG. 3 is a top view of an example ESC included in the substrate processing apparatus.

The ESC 217 has a mount surface facing the substrate 265 mounted on the mount 211. The mount surface is divided into multiple regions 266-1 to 266-n as shown in FIG. 3. The multiple regions 266-1 to 266-n may not be in the shape in the example shown in FIG. 3. The mount surface may be divided into multiple regions shaped differently from the multiple regions 266-1 to 266-n. The multiple regions 266-1 to 266-n correspond to the respective heaters 223-1 to 223-n. The heater 223-1 corresponding to the region 266-1 of the multiple heaters 223-1 to 223-n is embedded adjacent to the region 266-1 of the ESC 217. In response to receiving alternating current (AC) power, the heater 223-1 mainly heats the region 266-1 of the ESC 217. Similarly to the heater 223-1, in response to receiving AC power, the heaters other than the heater 223-1 of the multiple heaters 223-1 to 223-n also mainly heat the respective regions of the ESC 217 corresponding to the heaters of the multiple regions 266-1 to 266-n.

### (7) Structures of Multiple Power Supply Units 232-1 to 232-n

The multiple power supply units 232-1 to 232-n correspond to the multiple heaters 223-1 to 223-n. FIG. 4 is a circuit diagram of an example power supply unit included in the substrate processing apparatus.

The power supply unit 232-1 includes a switch 271 and a resistance sensor 272. The switch 271 is located in a heater power supply electric circuit 274 connecting an AC power supply 273 and the heater 223-1. The AC power supply 273 is located at a factory at which the substrate processing apparatus 110 is installed. The AC power supply 273 provides AC power to the substrate processing apparatus 110, and also provides AC power to devices other than the substrate processing apparatus 110. The switch 271 is closed to supply power from the AC power supply 273 to the heater 223-1, and opened to stop power from being provided from the AC power supply 273 to the heater 223-1.

The resistance sensor 272 includes a voltmeter 275 and an ammeter 276. The voltmeter 275 measures the voltage applied to the heater 223-1. The ammeter 276 includes a shunt resistor 277 and a voltmeter 278. The shunt resistor 277 is located in the heater power supply electric circuit 274. The shunt resistor 277 has a resistance value of, for example, 10 mΩ. The voltmeter 278 measures the voltage applied to the shunt resistor 277. The ammeter 276 measures the current flowing through the heater 223-1 based on the voltage measured by the voltmeter 278.

The resistance sensor 272 measures the electrical resistance of the heater 223-1 based on the voltage value measured by the voltmeter 275 and the current value measured by the ammeter 276. The electrical resistance of the heater 223-1 is equal to a value obtained by dividing the voltage measured by the voltmeter 275 by the current value measured by the ammeter 276. Similarly to the power supply unit 232-1, the other power supply units other than the power supply unit 232-1 of the multiple power supply units 232-1 to 232-n each include a switch and a resistance sensor. In other words, the substrate processing apparatus 110 includes multiple resistance sensors corresponding to the respective heaters 223-1 to 223-n. Similarly to the power supply unit 232-1, each power supply unit provides AC power from the AC power supply 273 to the corresponding heater of the multiple heaters 223-1 to 223-n and measures the electrical resistance of the heater.

### Hardware Configuration of Analysis Apparatus

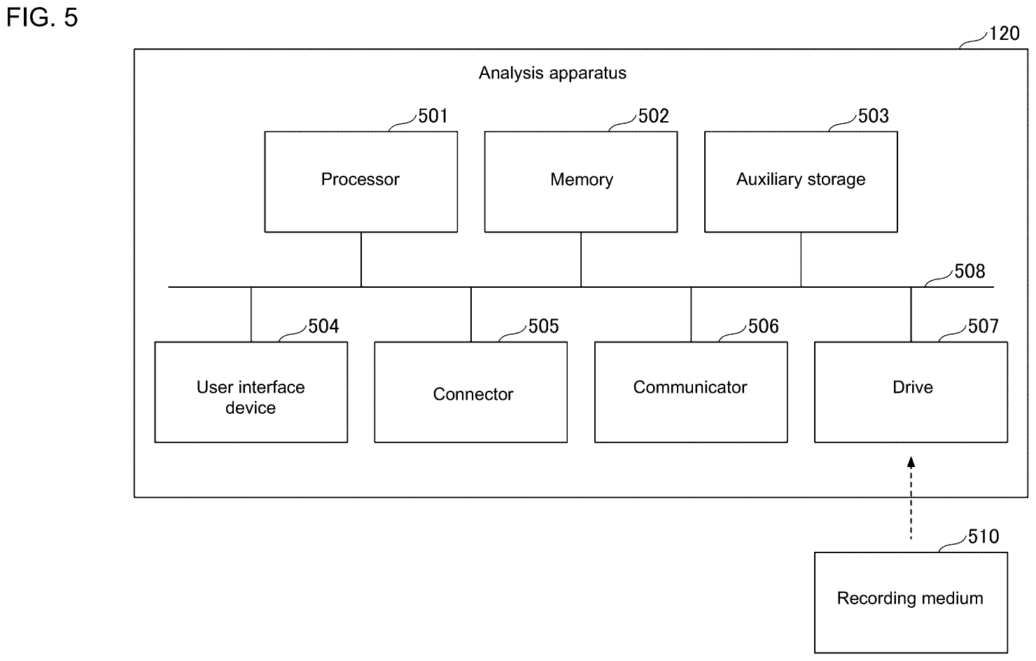

The hardware configuration of the analysis apparatus 120 will now be described. FIG. 5 is a block diagram of an analysis apparatus showing its example hardware configuration.

As shown in FIG. 5, the analysis apparatus 120 includes a processor 501, a memory 502, an auxiliary storage 503, a user interface device 504, a connector 505, a communicator 506, and a drive 507. The hardware components of the analysis apparatus 120 are interconnected with a bus 508.

The processor 501 includes various computing devices such as a central processing unit (CPU) and a graphics processing unit (GPU). The processor 501 reads and executes various programs (e.g., an analysis program described in detail later) on the memory 502.

The memory 502 includes a main storage such as a read-only memory (ROM) or a random-access memory (RAM). The processor 501 and the memory 502 are included in a computer. The computer implements various functions in the phases described above with the processor 501 executing the various programs read on the memory 502.

The auxiliary storage 503 stores the various programs and various sets of data used when the processor 501 executes the various programs.

The user interface device 504 includes, for example, a keyboard or a touchscreen used by a user of the analysis apparatus 120 to input various commands or perform other operations, and a display that displays the details of the processing performed by the analysis apparatus 120.

The connector 505 is a connection device that connects to another device (e.g., the substrate processing apparatus 110) in the substrate processing system 100. The communicator 506 is a communication device that communicates with an external device (not shown) through a network.

The drive 507 is a device in which a recording medium 510 is loaded. The recording medium 510 herein includes a medium that records information optically, electrically, or magnetically, such as a compact disc read-only memory (CD-ROM), a flexible disk, or a magneto-optical disk. The recording medium 510 may include, for example, a semiconductor memory that records information electrically, such as a ROM or a flash memory.

The various programs to be installed into the auxiliary storage 503 are, for example, stored in the recording medium 510 for distribution, and are read by the drive 507 from the recording medium 510 that is loaded in the drive 507. The various programs to be installed into the auxiliary storage 503 may be downloaded from the network through the communicator 506.

### Functional Components of Substrate Processing System in Pre-training Phase

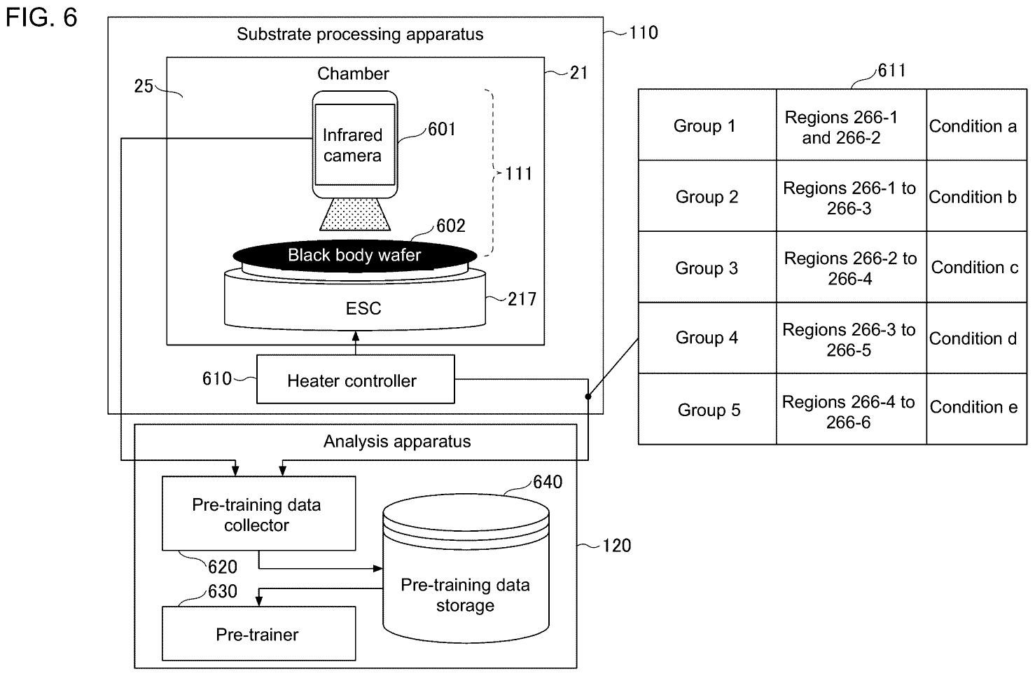

The functional components of the substrate processing system 100 in the pre-training phase will now be described in detail. FIG. 6 is a diagram of the substrate processing system (in the pre-training phase), showing its example functional components. As shown in FIG. 6, in the pre-training phase, the pre-training data measurement device 111 is installed in the chamber 21 in the substrate processing apparatus 110. More specifically, an infrared camera 601 is installed and a black body wafer 602 is supported by the ESC 217 in the processing space 25 in a vacuum environment (a first vacuum environment).

In the pre-training phase, the heaters 223-1 to 223-n in the regions 266-1 to 266-n of the ESC 217 are controlled by a heater controller 610. More specifically, the heaters 223-1 to 223-n controlled by the heater controller 610 operate at various setting temperatures.

In the pre-training phase, the infrared camera 601 photographs the black body wafer 602 from above and measures the surface temperature of the black body wafer 602 when the heaters 223-1 to 223-n operate at the various setting temperatures, and obtains the measured temperatures. For ease of explanation, n is hereafter 6.

In FIG. 6, a table 611 shows combinations of the setting temperatures set for the heaters 223-1 to 223-6 by the heater controller 610. In the present embodiment, as shown in the table 611, combinations of the regions of the ESC and the setting temperatures are divided into five groups. For each group, combinations of multiple different setting temperatures (a to e patterns of conditions) are extracted based on an orthogonal array. Although the combinations of the regions of the ESC and the setting temperatures are divided into, for example, the five groups based on the orthogonal array in the embodiment of the disclosure, the number of groups is not limited to this example.

The analysis program is installed in the analysis apparatus 120. In the pre-training phase, the program is executed to cause the analysis apparatus 120 to function as a pre-training data collector 620 and a pre-trainer 630.

The pre-training data collector 620 obtains, from the heater controller 610, the combinations of the setting temperatures for the heaters 223-1 to 223-6 in the regions 266-1 to 266-6, and obtains the respective measured temperatures from the infrared camera 601. The pre-training data collector 620 stores, into a pre-training data storage 640 (an example of a storage), the pre-training data including the obtained combinations of the setting temperatures as input data, and the measured temperatures at the positions on the substrate as measurement data.

The pre-trainer 630 is an example of a trainer and includes a temperature estimation model. The pre-trainer 630 reads the pre-training data stored in the pre-training data storage 640, and performs pre-training on the temperature estimation model to cause the temperature estimation model to output data closer to the measurement data when the input data is input into the temperature estimation model.

### Specific Examples of Pre-training Data and Processing Performed by Pre-trainer

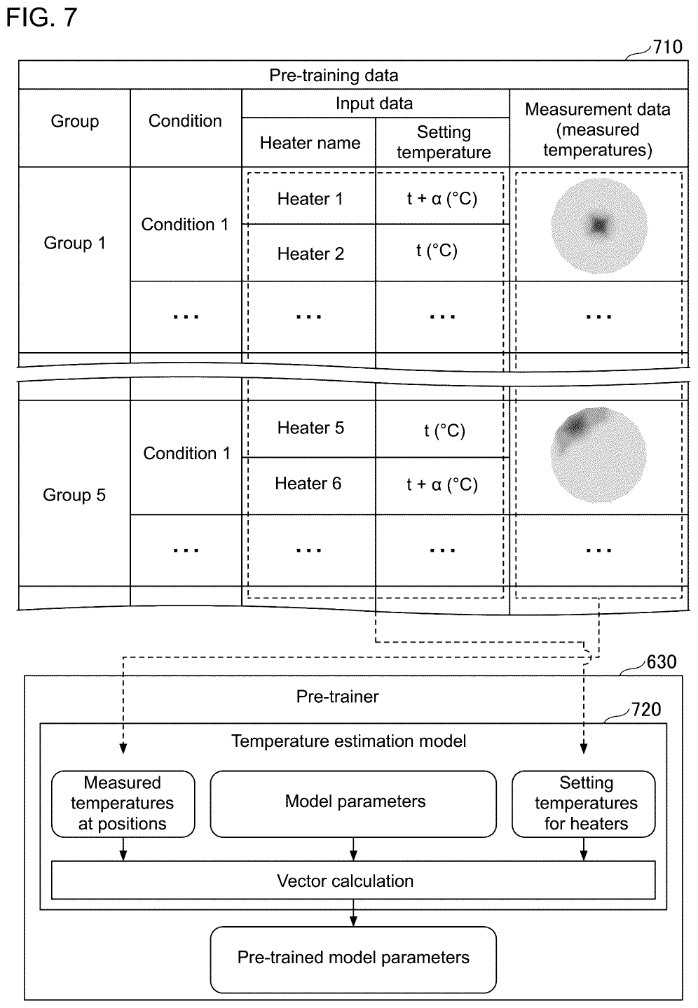

A specific example of pre-training data stored in the pre-training data storage 640 and a specific example of processing performed by the pre-trainer 630 using the pre-training data will now be described. FIG. 7 is a diagram showing specific examples of pre-training data and processing performed by a pre-trainer.

As shown in FIG. 7, pre-training data 710 includes Group, Condition, Input data, and Measurement data as the items of information. The group includes the name of one of the five groups divided to store the combinations of the setting temperatures to be extracted. The Condition stores information identifying one of the combinations of the heaters and the setting temperatures (a to e patterns of conditions) in each group.

Heater name and setting temperature are further included in the Input data. The Heater name stores the names of the heaters for which the setting temperatures are set. The Setting temperature stores the setting temperatures set for the heaters.

The Measurement data stores the measured temperatures at the positions (a first temperature data set), which are each obtained by the infrared camera 601 that measures the surface temperature of the black body wafer 602 when the heaters operate with the combination of the setting temperatures stored in the corresponding input data. In FIG. 7, the differences in color between the positions represent the differences between the measured temperatures at the positions.

As shown in FIG. 7, the pre-trainer 630 includes a temperature estimation model 720. The temperature estimation model 720 is trained using vector calculation for the relationships between the measured temperatures at the positions, model parameters, and the setting temperatures for the heaters to calculate the pre-trained model parameters.

More specifically, the pre-trainer 630 inputs the input data (setting temperatures set for the heaters 223-1 to 223-6) into the temperature estimation model 720. The pre-trainer 630 updates the model parameters to cause the output data output by multiplying the model parameters to be closer to the measurement data (measured temperatures at the positions). In this manner, the pre-trainer 630 calculates the pre-trained model parameters (first model parameters).

### Functional Components of Substrate Processing System in Additional Training Phase

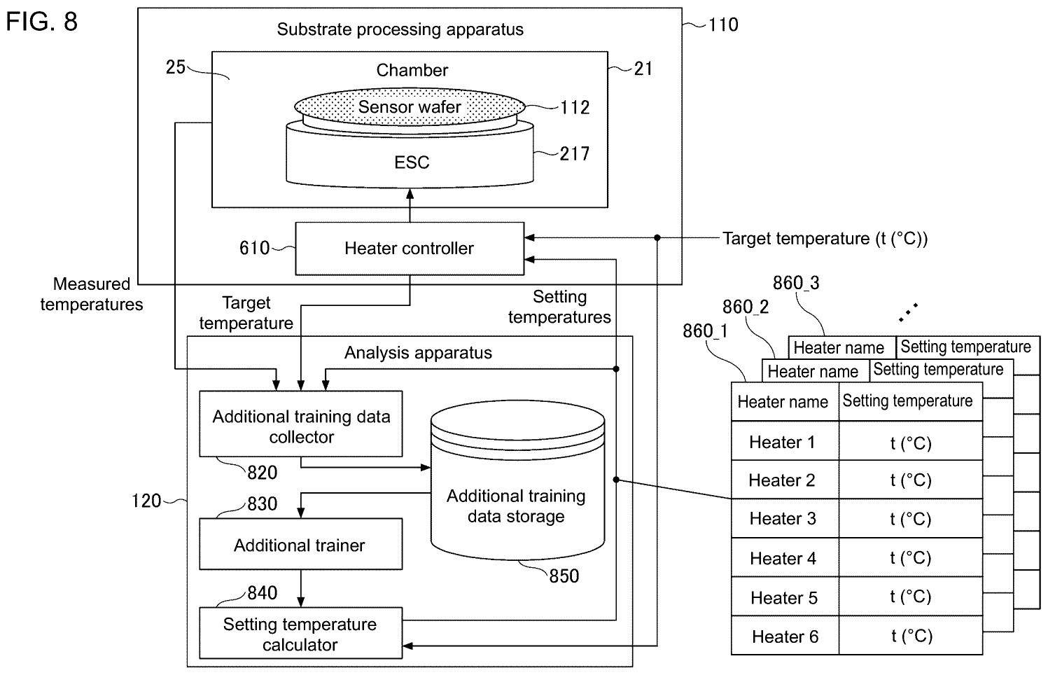

The functional components of the substrate processing system 100 in the additional training phase will now be described. FIG. 8 is a diagram of the substrate processing system (in the additional training phase), showing its example functional components. As shown in FIG. 8, in the additional training phase, the sensor wafer 112 is loaded in the chamber 21 in the substrate processing apparatus 110. More specifically, the sensor wafer 112 is supported by the ESC 217 in the processing space 25 in the vacuum environment (e.g., a second vacuum environment). In the present embodiment, as described above, the substrate processing apparatus 110 used in the additional training phase and the substrate processing apparatus 110 used in the pre-training phase are separate substrate processing apparatuses. Thus, the processing space 25 in the vacuum environment in this phase and the processing space 25 in the vacuum environment in the pre-training phase are processing spaces in separate vacuum environments.

As shown in FIG. 8, in the additional training phase, the heaters 223-1 to 223-6 in the regions 266-1 to 266-6 of the ESC 217 are controlled by the heater controller 610 and operate at the setting temperatures corresponding to the target temperature. The setting temperatures corresponding to the target temperature in this phase are calculated by a setting temperature calculator 840 (to be described later) based on the pre-trained model parameters and the target temperature. In the example in FIG. 8, t° C. is set for the heaters 223-1 to 223-6 as the setting temperatures corresponding to the target temperature (t° C.) (refer to the reference numeral 860_1).

In the additional training phase, the sensor wafer 112 measures temperatures when the heaters 223-1 to 223-6 operate at the setting temperatures corresponding to the target temperature, and obtains the measured temperatures.

The analysis program is installed in the analysis apparatus 120. In the additional training phase, the program is executed to cause the analysis apparatus 120 to function as an additional training data collector 820, an additional trainer 830, and the setting temperature calculator 840.

The additional training data collector 820 obtains the target temperature input into the heater controller 610, the setting temperatures calculated by the setting temperature calculator 840 and notified to the heater controller 610, and the measured temperatures measured by the sensor wafer 112 in response to the heaters 223-1 to 223-6 operating at the setting temperatures.

The additional training data collector 820 stores, into an additional training data storage 850, the additional training data in a manner associated with the target temperature. The additional training data includes the obtained setting temperatures for the heaters 223-1 to 223-6 as input data and the corresponding measured temperatures as measurement data.

The additional training data collector 820 determines whether the obtained measured temperatures satisfy a predetermined condition and notifies the additional trainer 830 of the determination result.

The additional trainer 830 includes the pre-trained temperature estimation model, and operates when receiving, from the additional training data collector 820, the determination result indicating that the predetermined condition is not satisfied. More specifically, the additional trainer 830 reads the additional training data stored in the additional training data storage 850. The additional trainer 830 performs additional training on the pre-trained temperature estimation model to cause the pre-trained temperature estimation model to output data closer to the measurement data when the input data is input into the pre-trained temperature estimation model.

The setting temperature calculator 840 newly calculates the setting temperatures corresponding to the target temperature, using the additionally trained model parameters (e.g., second model parameters) generated through the additional training performed by the additional trainer 830. In other words, the setting temperatures corresponding to the target temperature in this phase are calculated based on the additionally trained model parameters and the target temperature. The setting temperature calculator 840 notifies the heater controller 610 of the newly calculated setting temperatures (refer to, for example, the reference numeral 860_2).

The processing performed by each of the additional training data collector 820, the additional trainer 830, and the setting temperature calculator 840 is repeatedly performed until the measured temperatures measured by the sensor wafer 112 are determined to satisfy the predetermined condition. In FIG. 8, the reference numerals 860_1, 860_2, 860_3, . . . indicate that the setting temperature calculator 840 has notified the heater controller 610 of new setting temperatures multiple times.

### Specific Examples of Additional Training Data and Processing Performed by Additional Trainer and Setting Temperature Calculator

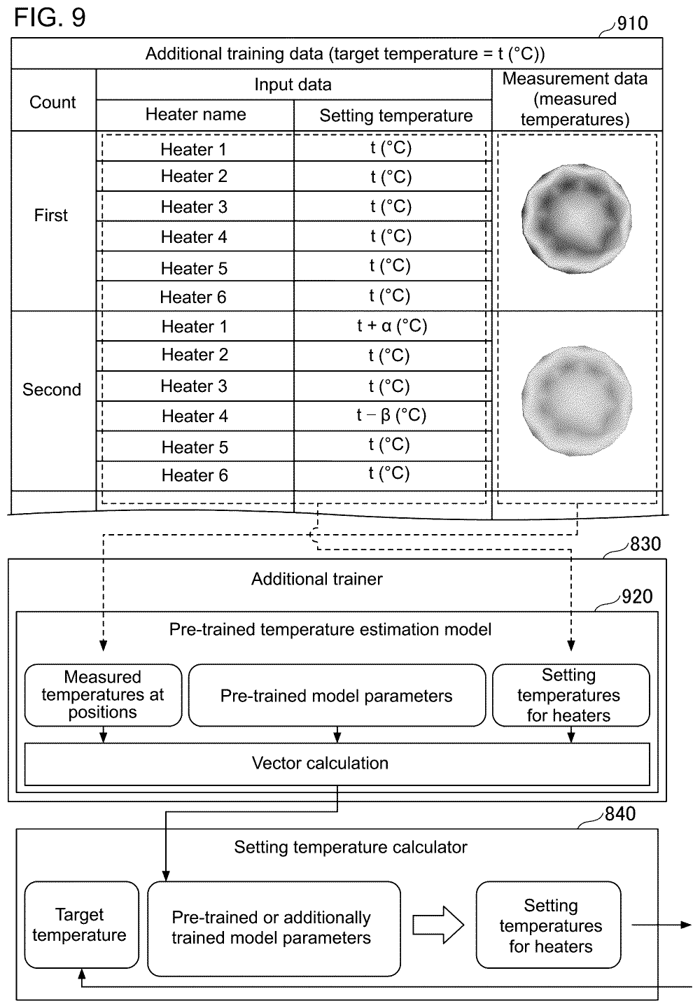

A specific example of additional training data stored in the additional training data storage 850 and a specific example of processing performed by the additional trainer 830 using the additional training data and processing performed by the setting temperature calculator 840 are now described. FIG. 9 is a diagram showing specific examples of additional training data and processing performed by an additional trainer and a setting temperature calculator.

As shown in FIG. 9, additional training data 910 includes Count, Input data, and Measurement data as the items of information. The Count stores the number of times the setting temperatures are set to the heater controller 610. Heater name and Setting temperature are further included in the Input data. The Heater name stores the names of the heaters 223-1 to 223-6 for which the setting temperatures are set. The Setting temperature stores the setting temperatures set for the respective heaters.

The Measurement data stores the measured temperatures (a second temperature data set), which are measured by the sensor wafer 112 when the heaters 223-1 to 223-6 operate at the setting temperatures stored in the corresponding input data.

As shown in FIG. 9, the additional trainer 830 includes a pre-trained temperature estimation model 920. In the pre-trained temperature estimation model 920, the relationships between the measured temperatures at the positions, the pre-trained model, and the setting temperatures for the heaters are trained using, for example, vector calculation, and the additionally trained model parameters are calculated.

More specifically, the additional trainer 830 inputs the input data (setting temperatures set for the heaters 223-1 to 223-6) into the pre-trained temperature estimation model 920. The additional trainer 830 updates pre-trained model parameters to cause the output data output by multiplying the pre-trained model parameters to be closer to the measurement data (measured temperatures at the positions). In this manner, the additional trainer 830 calculates the additionally trained model parameters.

The setting temperature calculator 840 first calculates the setting temperatures (setting temperatures set for the heaters 223-1 to 223-6) corresponding to the target temperature based on the pre-trained model parameters and the target temperature input into the heater controller 610. The setting temperature calculator 840 notifies the heater controller 610 of the calculated setting temperatures for the heaters 223-1 to 223-6.

The setting temperature calculator 840 can calculate the setting temperatures for the heaters corresponding to the target temperature by, for example, multiplying the opposite vectors of the pre-trained model parameters by the target temperature.

When the additional trainer 830 performs additional training, the setting temperature calculator 840 newly calculates the setting temperatures (setting temperatures set for the heaters 223-1 to 223-6) corresponding to the target temperature based on the additionally trained model parameters calculated by the additional trainer 830 and the target temperature input into the heater controller 610. The setting temperature calculator 840 notifies the heater controller 610 of the newly calculated setting temperatures for the heaters 223-1 to 223-6.

The setting temperature calculator 840 can calculate the setting temperatures for the heaters corresponding to the target temperature by, for example, multiplying the opposite vectors of the additionally trained model parameters by the target temperature.

The additional trainer 830 uses reliability to calculate the additionally trained model parameters. The reliability refers to the degree of contribution to the additionally trained model parameters by values of the pre-trained model parameters (e.g., elements in a vector) and values indicating the relationship between the setting temperatures corresponding to the target temperature and the measured temperatures, which are both the additional training data.

In this manner, the additionally trained model parameters are updated while the degree of contribution of the additional training data to the pre-trained model parameters is being increased. This allows the analysis apparatus 120 to generate appropriate model parameters that are not affected by any machine differences.

### Analysis Process

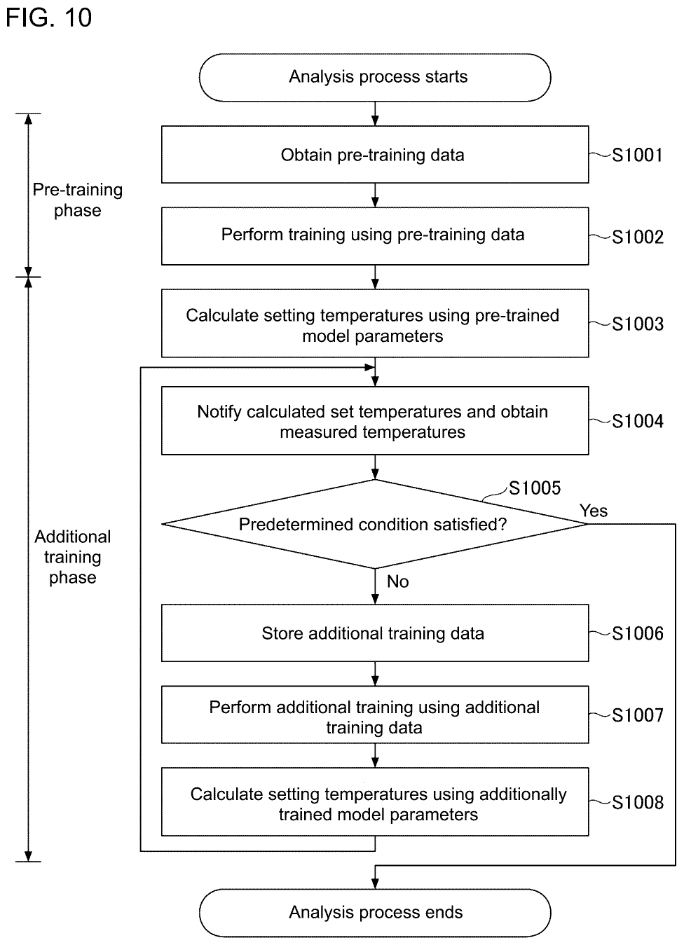

The analysis process performed by the analysis apparatus 120 from the pre-training phase through the additional training phase will now be described. FIG. 10 is a first flowchart of an example analysis process.

In step S1001, the analysis apparatus 120 obtains the pre-training data 710 from the substrate processing apparatus 110 in which the pre-training data measurement device 111 is installed.

In step S1002, the analysis apparatus 120 performs pre-training on the temperature estimation model 720 using the obtained pre-training data 710, and generates the pre-trained temperature estimation model 920.

In step S1003, the analysis apparatus 120 calculates, using the pre-trained model parameters, setting temperatures (setting temperatures set for the heaters 223-1 to 223-6) corresponding to the target temperature.

In step S1004, the analysis apparatus 120 operates the heaters 223-1 to 223-6 in the regions of the ESC 217 at the setting temperatures corresponding to the target temperature, with the sensor wafer 112 being supported. The analysis apparatus 120 then obtains measured temperatures.

In step S1005, the analysis apparatus 120 determines whether the obtained measured temperatures satisfy a predetermined condition. When the analysis apparatus 120 determines that the obtained measured temperatures do not satisfy the predetermined condition in step S1005 (No in step S1005), the processing advances to step S1006.

In step S1006, the analysis apparatus 120 stores the additional training data 910 including the setting temperatures as input data and the obtained measured temperatures as measurement data.

In step S1007, the analysis apparatus 120 performs additional training on the pre-trained temperature estimation model 920 using the additional training data 910, and generates an additionally trained temperature estimation model.

In step S1008, the analysis apparatus 120 newly calculates, using additionally trained model parameters, the setting temperatures (setting temperatures set for the heaters 223-1 to 223-6) corresponding to the target temperature. The processing then returns to step S1004.

When the analysis apparatus 120 determines that the obtained measured temperatures satisfy the predetermined condition in step S1005 (Yes in step S1005), the analysis apparatus 120 ends the analysis process.

### Changes in Adjustment Accuracy

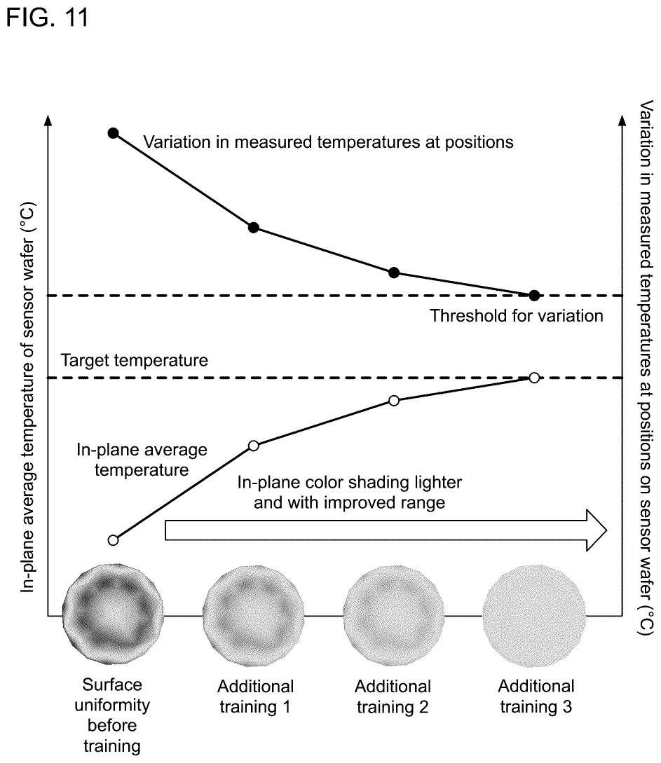

Changes in the adjustment accuracy in the additional training phase will now be described. FIG. 11 is a graph showing example changes in the adjustment accuracy. In FIG. 11, the horizontal axis indicates the number of times the setting temperature calculator 840 calculates new setting temperatures after the additional training is performed in the additional training phase. Of the vertical axes, the left vertical axis indicates the average (in-plane average temperature) of the measured temperatures at the positions measured by the sensor wafer 112, and the right vertical axis indicates the variation in the measured temperatures at positions measured by the sensor wafer 112.

As shown in FIG. 11, in the additional training phase, each time the setting temperature calculator 840 calculates new setting temperatures, the in-plane average temperature approaches the target temperature and the variation in the measured temperatures at the positions on the substrate decreases.

### Overview

As described above, the analysis apparatus 120 according to the first embodiment obtains, as pre-training data, the setting temperatures for the heaters in the regions divided from the ESC and the temperatures measured at positions on the substrate supported by the ESC in the processing space in the vacuum environment, and performs pre-training to generate a pre-trained temperature estimation model. The analysis apparatus 120 includes the temperature setting calculator that calculates, using the pre-trained temperature estimation model (using the pre-trained model parameters), setting temperatures for the heaters corresponding to the target temperature of the substrate.

As described above, the analysis apparatus 120 according to the first embodiment learns the relationship between the setting temperatures for the heaters and the temperatures measured when the heaters operate at the setting temperatures, and calculates setting temperatures corresponding to the target temperature using the trained model parameters.

The analysis apparatus 120 according to the first embodiment can thus avoid a decrease in the adjustment accuracy, such as the in-plane average temperature of the substrate that is different from the target temperature due to locally uneven temperatures caused by, for example, machine differences.

In other words, the analysis apparatus according to the first embodiment can improve the adjustment accuracy in adjusting the temperature of a substrate.

### Second Embodiment

In the first embodiment, determination is performed, in the analysis process, as to whether the measured temperatures satisfy the predetermined condition before performing additional training. The processing in the analysis process may not be performed in this order. For example, additional training may be performed before determination is performed as to whether the measured temperatures satisfy the predetermined condition. The second embodiment will be described below, focusing on the differences from the first embodiment. Analysis Process

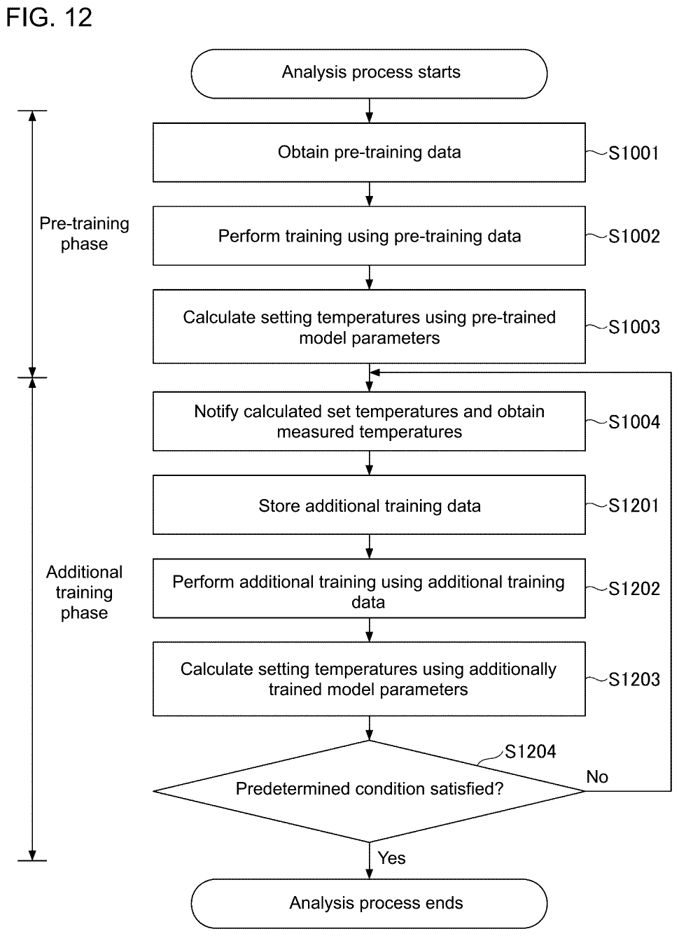

FIG. 12 is a second flowchart of an example analysis process. The differences from the first flowchart shown in FIG. 10 are steps S1201 to S1204. Steps S1201 to S1204 will thus be described.

In step S1201, the analysis apparatus 120 stores the additional training data 910 including the setting temperatures as input data and the obtained measured temperatures as measurement data.

In step S1202, the analysis apparatus 120 performs, on the pre-trained temperature estimation model 920, additional training using the additional training data 910 and generates an additionally trained temperature estimation model.

In step S1203, the analysis apparatus 120 newly calculates, using additionally trained model parameters, the setting temperatures (setting temperatures set for the heaters 223-1 to 223-6) corresponding to the target temperature.

In step S1204, the analysis apparatus 120 determines whether the obtained measured temperatures satisfy a predetermined condition. When the analysis apparatus 120 determines that the obtained measured temperatures do not satisfy the predetermined condition in step S1204 (No in step S1204), the processing returns to step S1004.

When the analysis apparatus 120 determines that the obtained measured temperatures satisfy the predetermined condition in step S1204 (Yes in step S1204), the analysis apparatus 120 ends the analysis process.

### Overview

As described above, the analysis apparatus 120 according to the second embodiment produces the same effects as the structure in the first embodiment when the processing in the analysis process is performed in a different order.

### Third Embodiment

In the above embodiments, the heaters 223-1 to 223-6 are located in the regions 266-1 to 266-6 of the ESC. However, the temperature adjustment elements located in the regions 266-1 to 266-6 of the ESC are not limited to heaters. Other temperature adjustment elements such as thermistors or Peltier elements may be used. When other temperature adjustment elements are located in the regions 266-1 to 266-6, other setting parameters are set for the other temperature adjustment elements in place of the electrical resistances.

Although the substrate processing method performed by the substrate processing apparatus 110 is not described in detail in the above embodiments, the substrate processing apparatus 110 may use, for example, a plasma etching method. In this case, the processing space 25 in the vacuum environment refers to the processing space 25 in a plasma processing environment. However, the processing space 25 in the vacuum environment may be a processing space in an environment other than the plasma processing environment.

Although the substrate processing apparatus 110 and the analysis apparatus 120 are separate from each other in the substrate processing system 100 in the first embodiment, the substrate processing apparatus 110 and the analysis apparatus 120 may be integral with each other. The functions of the analysis apparatus 120 may be implemented partially by the substrate processing apparatus 110.

In the first embodiment, the analysis apparatus 120 alone executes the analysis program. However, when the analysis apparatus 120 includes, for example, multiple computers in which the analysis program is installed, the analysis program may be executed by distributed computing.

In the first embodiment, the example method for installing the analysis program in the auxiliary storage 503 includes downloading the program from the network (not shown) and installing the program. Although not particularly described above, the source from which the analysis program to be installed with the above method may be, for example, a server that stores the analysis program in an accessible manner. The server may allow the analysis apparatus 120 to access the server through the network (not shown) and allow the analysis apparatus 120 to download the analysis program on the condition that payment is received. In other words, the server may be a device that provides a service to provide the analysis program in the cloud.

One or more embodiments of the disclosure are implementable in forms defined in the appendixes below.

### Appendix 1

An analysis apparatus, comprising:

a trainer configured to perform training to generate a trained model using setting parameters for temperature adjustment elements in regions divided from a substrate support in a process space in a first vacuum environment and using a first temperature data set, the first temperature data set being data of temperatures at positions on a substrate supported by the substrate support; and

a calculator configured to calculate setting parameters for the temperature adjustment elements corresponding to a target temperature of the substrate using the trained model.

### Appendix 2

The analysis apparatus according to appendix 1, further comprising:

a storage configured to store, as training data, the setting parameters for the temperature adjustment elements in the regions divided from the substrate support in the process space in the first vacuum environment and the first temperature data set, the first temperature data set being the data of the temperatures at the positions on the substrate supported by the substrate support,

wherein the trained model is generated through training on a model using the training data read from the storage.

### Appendix 3

The analysis apparatus according to appendix 1, further comprising:

an additional trainer configured to additionally train the trained model to generate an additionally trained model using setting parameters calculated by the calculator in a process space in a second vacuum environment and a second temperature data set, the second temperature data set being data of temperatures at the positions on the substrate measured when the temperature adjustment elements operate based on the setting parameters calculated by the calculator.

### Appendix 4

The analysis apparatus according to appendix 3, wherein the calculator calculates the setting parameters for the temperature adjustment elements corresponding to the target temperature of the substrate using the additionally trained model.

### Appendix 5

The analysis apparatus according to appendix 4, wherein the calculator and the additional trainer repeat processing until the second temperature data set is determined to satisfy a predetermined condition for the target temperature.

### Appendix 6

The analysis apparatus according to any one of appendixes 1 to 5, wherein the trainer calculates first model parameters between the setting parameters and the first temperature data set.

### Appendix 7

The analysis apparatus according to any one of appendixes 3 to 5, wherein the additional trainer calculates second model parameters between the setting parameters and the second temperature data set.

### Appendix 8

The analysis apparatus according to any one of appendixes 3 to 5, wherein the first temperature data set and the second temperature data set are measured with an infrared camera or a sensor wafer.

### Appendix 9

The analysis apparatus according to any one of appendixes 1 to 8, wherein the first vacuum environment is a plasma processing environment.

### Appendix 10

The analysis apparatus according to any one of appendixes 3 to 5, wherein at least one of the first vacuum environment or the second vacuum environment is a plasma processing environment.

Appendix 11

The analysis apparatus according to any one of appendixes 3 to 5, wherein the first vacuum environment and the second vacuum environment are in a same process space.

### Appendix 12

The analysis apparatus according to any one of appendixes 1 to 11, wherein the temperature adjustment elements are heaters, thermistors, or Peltier elements.

### Appendix 13

The analysis apparatus according to appendix 12, wherein the setting parameters are electrical resistances of the heaters.

### Appendix 14

A substrate processing system, comprising:

the analysis apparatus according to any one of appendixes 1 to 13; and a substrate processing apparatus including temperature adjustment elements in regions divided from a substrate support in a process space in a vacuum environment.

### Appendix 15

A substrate processing apparatus including temperature adjustment elements in regions divided from a substrate support in a process space in a vacuum environment, the substrate processing apparatus comprising:

a trainer configured to perform training to generate a trained model using setting parameters for the temperature adjustment elements and using a first temperature data set, the first temperature data set being data of temperatures at positions on a substrate supported by the substrate support; and

a calculator configured to calculate setting parameters for the temperature adjustment elements corresponding to a target temperature of the substrate, using the trained model.

### Appendix 16

An analysis method, comprising:

performing training to generate a trained model using setting parameters for temperature adjustment elements in regions divided from a substrate support in a process space in a vacuum environment and using a first temperature data set, the first temperature data set being data of temperatures at positions of a substrate supported by the substrate support; and

calculating setting parameters for the temperature adjustment elements corresponding to a target temperature of the substrate using the trained model.

### Appendix 17

An analysis program for causing a computer to perform operations comprising:

performing training to generate a trained model using setting parameters for temperature adjustment elements in regions divided from a substrate support in a process space in a vacuum environment and using a first temperature data set, the first temperature data set being data of temperatures at positions of a substrate supported by the substrate support; and

calculating setting parameters for the temperature adjustment elements corresponding to a target temperature of the substrate using the trained model.

The present invention is not limited to the structures described herein, and the structures described in the above embodiments may be, for example, combined with other elements. The structures may be modified without departing from the spirit of the present invention and may be defined as appropriate for forms of applications.

This application claims priority to Japanese Patent Application No. 2022-048877, filed on Mar. 24, 2022, the entire contents of which are incorporated herein by reference.

### REFERENCE SIGNS LIST

100 Substrate processing system
110 Substrate processing apparatus
111 Pre-training data measurement device
112 Sensor wafer
120 Analysis apparatus
610 Heater controller
620 Pre-training data collector
630 Pre-trainer
710 Pre-training data
720 Temperature estimation model
820 Additional training data collector
830 Additional trainer
840 Setting temperature calculator
910 Additional training data
920 Pre-trained temperature estimation model

1. An analysis apparatus, comprising:
circuitry configured to:
perform training to generate a trained model using setting parameters for temperature adjustment elements in regions divided from a substrate support in a process space in a first vacuum environment and using a first temperature data set, the first temperature data set being data of temperatures at positions on a substrate supported by the substrate support,
calculate setting parameters for the temperature adjustment elements corresponding to a target temperature of the substrate using the trained model, and
set the temperature adjustment elements in accordance with the calculated setting parameters.

2. The analysis apparatus according to claim 1, further comprising:
a storage for storing, as training data, the setting parameters for the temperature adjustment elements
wherein the trained method data read from the storage.

3. The analysis apparatus according to claim 1, further comprising:
circuitry is further configured to additionally train the trained model to generate an additionally trained model using the calculated setting parameters in a process space in a second vacuum environment and a second temperature data set, the second temperature data set being data of temperatures at the positions on the substrate measured when the temperature adjustment elements operate based on the calculated setting parameters.

4. The analysis apparatus according to claim 3, wherein
the circuitry is further configured to calculate the setting parameters for the temperature adjustment elements corresponding to the target temperature of the substrate using the additionally trained model.

5. The analysis apparatus according to claim 4, wherein
the circuitry is configured to repeat processing until the second temperature data set is determined to satisfy a predetermined condition for the target temperature.

6. The analysis apparatus according to claim 1, wherein
the circuitry is configured calculate first model parameters between the setting parameters and the first temperature data set.

7. The analysis apparatus according to claim 3, wherein
the circuitry is configured calculate second model parameters between the setting parameters and the second temperature data set.

8. The analysis apparatus according to claim 3, wherein
the first temperature data set and the second temperature data set are measured with an infrared camera or a sensor wafer.

9. The analysis apparatus according to claim 1, wherein
the first vacuum environment is a plasma processing environment.

10. The analysis apparatus according to claim 3, wherein
at least one of the first vacuum environment or the second vacuum environment is a plasma processing environment.

11. The analysis apparatus according to claim 3, wherein
the first vacuum environment and the second vacuum environment are in a same process space.

12. The analysis apparatus according to claim 1, wherein
the temperature adjustment elements are heaters, thermistors, or Peltier elements.

13. The analysis apparatus according to claim 12, wherein
the setting parameters are electrical resistances of the heaters.

14. A substrate processing system, comprising:
the analysis apparatus according to claim 1; and
a substrate processing apparatus including temperature adjustment elements in regions divided from a substrate support in a process space in a vacuum environment.

15. A substrate processing apparatus, comprising:
temperature adjustment elements in regions divided from a substrate support in a process space in a vacuum environment; and
circuitry configured to:
perform training to generate a trained model using setting parameters for the temperature adjustment elements and using a first temperature data set, the first temperature data set being data of temperatures at positions on a substrate supported by the substrate support,
calculate setting parameters for the temperature adjustment elements corresponding to a target temperature of the substrate, using the trained model, and
set the temperature adjustment elements in accordance with the calculated setting parameters.

16. An analysis method, comprising:
performing training to generate a trained model using setting parameters for temperature adjustment elements in regions divided from a substrate support in a process space in a vacuum environment and using a first temperature data set, the first temperature data set being data of temperatures at positions of a substrate supported by the substrate support; and
calculating setting parameters for the temperature adjustment elements corresponding to a target temperature of the substrate using the trained model; and
setting the temperature adjustment elements in accordance with the calculated setting parameters.

17. The analysis method according to claim 16, further comprising:
additionally training the trained model to generate an additionally trained model using the calculated setting parameters in a process space in a second vacuum environment and a second temperature data set, the second temperature data set being data of temperatures at the positions on the substrate measured when the temperature adjustment elements operate based on the calculated setting parameters.

18. The analysis method according to claim 17, further comprising:
calculating the setting parameters for the temperature adjustment elements corresponding to the target temperature of the substrate using the additionally trained model.

19. The analysis method according to claim 18, further comprising:
repeat processing until the second temperature data set is determined to satisfy a predetermined condition for the target temperature.

20. An analysis program for causing a computer to perform operations comprising:
performing training to generate a trained model using setting parameters for temperature adjustment elements in regions divided from a substrate support in a process space in a vacuum environment and using a first temperature data set, the first temperature data set being data of temperatures at positions of a substrate supported by the substrate support; and
calculating setting parameters for the temperature adjustment elements corresponding to a target temperature of the substrate using the trained model; and
set the temperature adjustment elements in accordance with the calculated setting parameters.
